(19) United States
(12) Patent Application Publication
(10) Pub. No.: US 2024/0234348 A9
(43) Pub. Date: Jul. 11, 2024

(54) SEMICONDUCTOR DEVICE, POWER CONVERSION DEVICE, AND METHOD OF MANUFACTURING SEMICONDUCTOR DEVICE

(71) Applicant: Mitsubishi Electric Corporation, Tokyo (JP)

(72) Inventors: Yasunari HINO, Tokyo (JP); Junichi YAMASHITA, Tokyo (JP); Koji TANAKA, Tokyo (JP); Tomohide TERASHIMA, Tokyo (JP); Shinichi IZUO, Tokyo (JP)

(73) Assignee: Mitsubishi Electric Corporation, Tokyo (JP)

(21) Appl. No.: 18/359,096

(22) Filed: Jul. 26, 2023

(30) Foreign Application Priority Data
Oct. 21, 2022 (JP) 2022-169074

(51) Int. Cl. H01L 23/00; H01L 23/49; H02M 7/44

(52) U.S. Cl. CPC H01L 24/05; H01L 23/49; H01L 24/03; H01L 24/04; H01L 24/45; H01L 24/48; H02M 7/44; H01L 24/29; H01L 24/32; H01L 24/73; H01L 2224/03334; H01L 2224/037; H01L 2224/0381; H01L 2224/04042; H01L 2224/05083; H01L 2224/05124; H01L 2224/05138; H01L 2224/05155; H01L 2224/05166; H01L 2224/05181; H01L 2224/05184; H01L 2224/05186; H01L 2224/05553; H01L 2224/05573; H01L 2224/05582; H01L 2224/05584; H01L 2224/05644; H01L 2224/05647; H01L 2224/05655; H01L 2224/0566; H01L 2224/29124; H01L 2224/29147; H01L 2224/32225; H01L 2224/45124; H01L 2224/45147; H01L 2224/48091; H01L 2224/48227; H01L 2224/73265; H01L 2924/01014; H01L 2924/0132; H01L 2924/01402; H01L 2924/04941; H01L 2924/04953; H01L 2924/10272; H01L 2924/1033; H01L 2924/12036; H01L 2924/13055; H01L 2924/13091

(57) ABSTRACT

Provided is a semiconductor device with higher reliability and longer life which can suppress an increase in production costs. A semiconductor device includes: a semiconductor element; a top electrode on an upper surface of the semiconductor element; and a conductive metal plate containing copper as a main component and solid-state diffusion bonded to the top electrode of the semiconductor element.

### BACKGROUND OF THE INVENTION

### Field of the Invention

The present disclosure relates to a semiconductor device, a power conversion device, and a method of manufacturing the semiconductor device.

### Description of the Background Art

Structures in each of which a copper (Cu) electrode made of Cu is formed on a top electrode of a semiconductor element and a wire made of a metal such as Al is bonded to the Cu electrode are known as example structures of semiconductor devices for power control. Japanese Patent Application Laid-Open No. 2006-86378 discloses a technology on a Cu electrode on a top electrode of a semiconductor element for reducing the resistance of the top electrode and enhancing the heat dissipation.

Recent years have seen an increased range of uses for the semiconductor devices for power control, and an increase in the currents of the semiconductor devices. Since the semiconductor devices for power control are used worldwide, support for the semiconductor devices under severe environments is sought. Here, the significant challenges are to pursue higher reliability and longer life of the semiconductor devices.

The structures in each of which a metal wire is directly bonded to a top electrode of a semiconductor element often have breaks caused by lift-off (peels) of wires. This creates a problem in pursuing higher reliability and longer life of the semiconductor devices.

As disclosed in Japanese Patent Application Laid-Open No. 2006-86378, the Cu electrode on the top electrode of the semiconductor element addresses the problem. However, forming Cu electrodes thick enough to endure the wire bonding requires Cu plating for enormous amounts of time. This leads to a problem of productivity. Plating technologies also require a great many processes including cleaning, drying, and resist processing. This poses other challenges such as a capital investment and reserving areas for installing facilities. Moreover, the plating technologies still have problems of non-uniform thicknesses and variations in appearance of plated films. Thus, the processes and the quality on the plated films need to be managed in detail. These incur an increase in the production costs.

### SUMMARY

The object of the present disclosure is to provide a semiconductor device with higher reliability and longer life which can suppress an increase in production costs.

The semiconductor device according to the present disclosure includes: a semiconductor element; a top electrode on an upper surface of the semiconductor element; and a conductive metal plate containing copper as a main component and solid-phase diffusion bonded to the top electrode of the semiconductor element.

The present disclosure can provide a semiconductor device with higher reliability and longer life which can suppress an increase in production costs.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a semiconductor device according to Embodiment 1;

FIG. 2 illustrates a cross-sectional view of a semiconductor element according to Embodiment 1;

FIG. 3 illustrates an example top surface structure of the semiconductor element according to Embodiment 1;

FIG. 4 illustrates an example top surface structure of the semiconductor element according to Embodiment 1;

FIG. 5 illustrates an example top surface structure of the semiconductor element according to Embodiment 1;

FIG. 6 is a flowchart illustrating a step for solid-phase diffusion bonding conductive metal plates to the semiconductor element in a method of manufacturing the semiconductor device according to Embodiment 1;

FIG. 7 illustrates a modified flowchart illustrating a step for solid-phase diffusion bonding the conductive metal plates to the semiconductor element;

FIG. 8 illustrates a cross-sectional view of the semiconductor element that is a p-n junction diode;

FIG. 9 illustrates a cross-sectional view of the semiconductor element that is a planar-gate MOSFET;

FIG. 10 illustrates a cooler attached to the semiconductor device according to Embodiment 1;

FIG. 11 illustrates a cross-sectional view of a semiconductor element according to Embodiment 2;

FIG. 12 illustrates a cross-sectional view of a semiconductor element according to Embodiment 3;

FIG. 13 illustrates a cross-sectional view of a part of a semiconductor device according to Embodiment 3; and

FIG. 14 is a block diagram illustrating a configuration of a power conversion system to which a power conversion device according to Embodiment 4 has been applied.

### DESCRIPTION OF THE PREFERRED EMBODIMENTS

### Embodiment 1

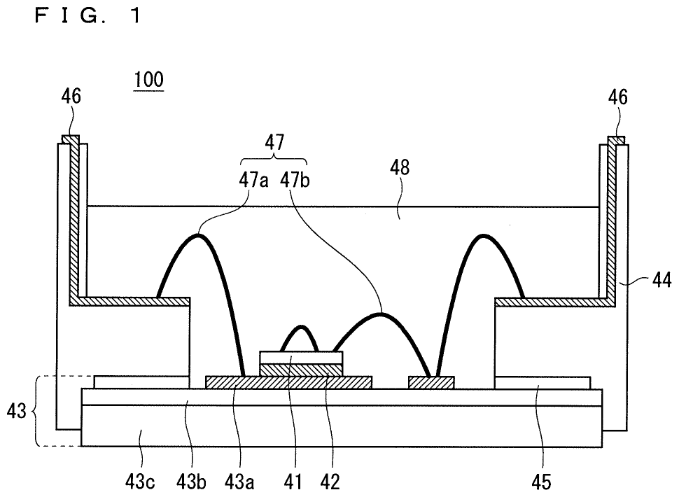

FIG. 1 is a cross-sectional view illustrating a semiconductor device 100 according to Embodiment 1.

The semiconductor device 100 includes at least one semiconductor element 41 mounted on an insulating substrate 43. The number of the semiconductor elements 41 may be any. The semiconductor elements 41 should be mounted as many as required to correspond to a specification of the semiconductor device 100. In Embodiment 1, the semiconductor element 41 is made of silicon (Si), and is what is called a power semiconductor element for controlling the power. Representative examples of the power semiconductor element include an insulated-gate bipolar transistor (IGBT), a metal-oxide-semiconductor field-effect transistor (MOSFET), and a freewheeling diode (FWD). One side of the semiconductor element 41 is approximately 1 mm to 20 mm long.

The semiconductor element 41 may contain a wide-bandgap semiconductor such as silicon carbide (SiC) or gallium nitride (GaN), besides Si. The semiconductor device 100 including the semiconductor element 41 containing a wide-bandgap semiconductor is superior to a semiconductor device including a semiconductor element containing Si in operating with a high voltage, with a large current, and at a high temperature.

The insulating substrate 43 has a laminated structure obtained by laminating abase plate 43c, an insulating layer 43b, and a circuit pattern 43a in this order from the bottom. The semiconductor element 41 is mounted on the circuit pattern 43a of the insulating substrate 43 through a bonding material 42. The bonding material 42 is a conductive metal containing Sn, that is, solder. Since the semiconductor element 41 generates heat, the bonding material 42 may be a sintered material higher in thermal conductivity and heat dissipation than solder, for example, a sintered material containing Ag or Cu particles.

The circuit pattern 43a is made of a conductive metal containing copper (Cu) or aluminum (Al). The thickness of the circuit pattern 43a is set according to a current density or an exotherm temperature when the semiconductor device 100 is energized, for example, approximately 0.2 mm to 0.5 mm. The insulating layer 43b is made of an epoxy resin to which fillers having a higher thermal conductivity and made of, for example, BN and Al₂O₃ have been added. The insulating layer 43b is approximately 0.2 mm to 1.0 mm thick. The base plate 43c is made of a metal having a higher thermal conductivity and containing Cu or Al. The base plate 43c is approximately 1.0 mm to 5.0 mm thick. The insulating substrate 43 requires a thermal conductivity higher than or equal to several tens of W/(m·K). Thus, a material of each of the circuit pattern 43a, the insulating layer 43b, and the base plate 43c is selected so that the insulating substrate 43 obtains an appropriate thermal conductivity corresponding to a thermal dissipation specification required for the semiconductor element 41.

Furthermore, the circuit pattern 43a and the insulating layer 43b of the insulating substrate 43 may form what is called a direct bonded copper (DBC) substrate. In other words, the insulating layer 43b may be made of ceramic such as Al₂O₃, AlN, or Si₃N₄. The insulating substrate 43 may have a structure in which the circuit pattern 43a and the insulating layer 43b are integrated and a metal plate (not illustrated) is bonded to a lower surface of the insulating layer 43b. Here, the metal plate on the lower surface of the insulating layer 43b is bonded to the base plate 43c through a bonding material such as solder.

A casing 44 for housing the semiconductor element 41 is bonded to the periphery of the insulating layer 43b of the insulating substrate 43 through an adhesive 45, and is secured. The casing 44 is made of, for example, a polyphenylene sulfide (PPS) resin or a polybutylene terephthalate (PBT) resin.

The casing 44 includes electrode terminals 46. The electrode terminals 46 are insert molded together with the casing 44, and embedded in the casing 44. As illustrated in FIG. 1, the electrode terminals 46 are bent, and one of the ends of each of the electrode terminals 46 protrudes from the casing 44 for the external connection. The other end of the electrode terminal 46 is exposed inside the casing 44.

The semiconductor element 41, the circuit pattern 43a, and the electrode terminals 46 are electrically connected to each other through metal wires 47 in the casing 44. As illustrated in FIG. 1, the metal wires 47 include a metal wire 47a for connecting the electrode terminal 46 to the circuit pattern 43a, and a metal wire 47b for connecting the semiconductor element 41 to the circuit pattern 43a. The metal wires 47 are made of a material containing Al and Cu. The diameter of the metal wires 47 is approximately 0.1 mm to 0.5 mm. The metal wires 47 are not limited to typical linear (wiry) ones but may be plate ribbon wires that can support a large current.

A sealant 48 fills the space inside the casing 44, that is, the space defined by the casing 44 and the insulating substrate 43, and seals the semiconductor element 41 and the metal wires 47. The sealant 48 is, for example, a gel-like silicone resin, or a thermosetting epoxy resin to which fillers containing SiO2 have been added. The material of the sealant 48 is not limited to these, and may be any plastic having a modulus of elasticity, a thermal conductivity, heat resistance, insulating properties, and adhesiveness that are required, for example, phenol resin or polyimide resin.

The adhesive 45 is a silicone-based adhesive. Alternatively, the adhesive 45 may be made of a material identical to that of the sealant 48. The adherence of the insulating layer 43b to the casing 44 through the adhesive 45 can prevent the sealant 48 from leaking from the casing 44.

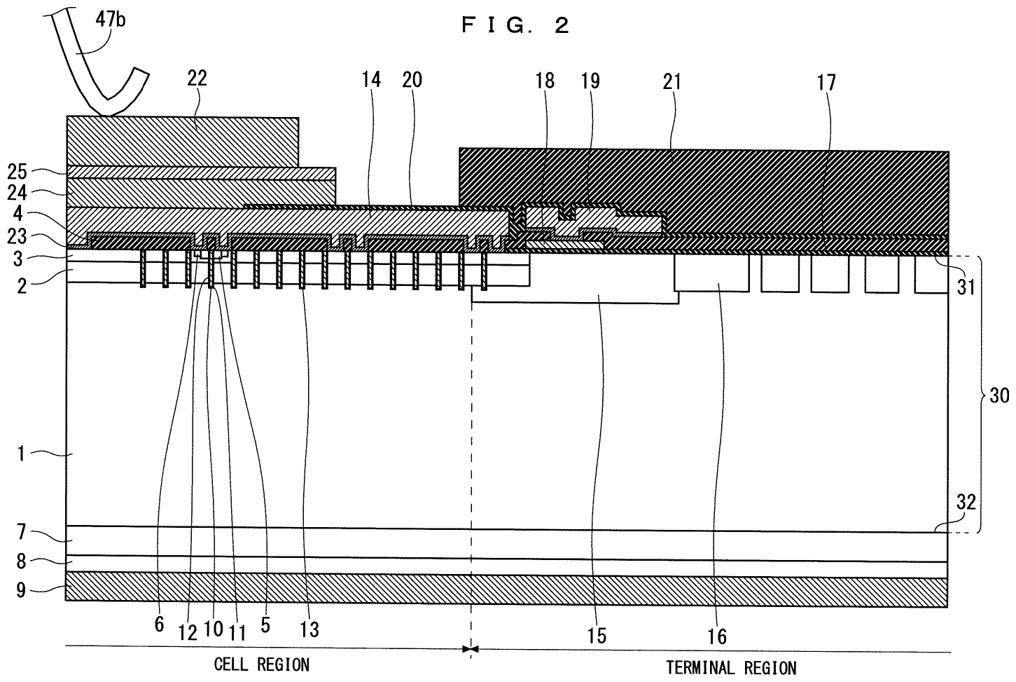

FIG. 2 illustrates a cross-sectional view of the semiconductor element 41. Here, the semiconductor element 41 is an insulated-gate bipolar transistor (IGBT). The semiconductor element 41 has a cell region in which IGBT cells are formed, and a terminal region outside the cell region. FIG. 2 illustrates a cross section at a boundary between the cell region and the terminal region. Although the first conductivity type is n-type and the second conductivity type is p-type in this description, conversely, the first conductivity type may be p-type and the second conductivity type may be n-type.

The semiconductor element 41 includes a semiconductor substrate 30 having a first principal surface 31 and a second principal surface 32. The semiconductor substrate 30 includes a drift layer 1 of the first conductivity type, between the first principal surface 31 and the second principal surface 32. The semiconductor substrate 30 may contain typical silicon (Si), or a wide-bandgap semiconductor, for example, silicon carbide (SiC).

The cell region includes a carrier storage layer 2 of the first conductivity type which is formed closer to the first principal surface 31 with respect to the drift layer 1 and which is higher in peak impurity concentration than the drift layer 1. The cell region further includes a base layer 3 of the second conductivity type in a surface layer of the semiconductor substrate 30 on the first principal surface 31 side. In a surface layer of the base layer 3, emitter layers 5 of the first conductivity type, and contact layers 6 of the second conductivity type which are higher in peak impurity concentration than the base layer 3 are selectively formed.

Active trenches 10 each reaching the drift layer 1 through the emitter layer 5, the base layer 3, and the carrier storage layer 2, and dummy trenches 13 each reaching the drift layer 1 through the base layer 3 and the carrier storage layer 2 in a region without the emitter layer 5 are formed from the first principal surface 31 of the semiconductor substrate 30. The dummy trenches 13 are formed to surround the active trenches 10. In each of the active trenches 10 and the dummy trenches 13, a gate electrode 12 is embedded through a gate insulating film 11. The gate electrode 12 in each of the dummy trenches 13 is a dummy electrode that does not contribute to switching between ON and OFF of the IGBT.

An interlayer insulating film 4 covering the active trenches 10 and the dummy trenches 13 is formed on the first principal surface 31 of the semiconductor substrate 30. A barrier metal 23 is formed on the interlayer insulating film 4, and an emitter electrode 14 that is a metal electrode made of a metal, for example, aluminum (Al) or AlSi is formed on the barrier metal 23. The emitter electrode 14 is connected to the emitter layers 5 and the contact layers 6 through the barrier metal 23 and contact holes formed in the interlayer insulating film 4.

The barrier metal 23 is a Ti layer or a W layer. The barrier metal 23 is approximately 10 nm to 300 nm thick. The barrier metal 23 may have a two-layer structure of a Ti layer and a W layer, or may be made of TiW. The barrier metal 23 may be made of Ta, TaN, or TiN.

A buffer layer 7 of the first conductivity type which is higher in peak impurity concentration than the drift layer 1 is formed on the second principal surface 32 with respect to the drift layer 1. Furthermore, a collector layer 8 of the second conductivity type is formed in a surface layer of the second principal surface 32 on the semiconductor substrate 30 side. A collector electrode 9 connected to the collector layer 8 is formed closer to the second principal surface 32 of the semiconductor substrate 30. These buffer layer 7, collector layer 8, and collector electrode 9 are formed not only in the cell region but also in the terminal region.

The terminal region includes, on the first principal surface 31 in the surface layer of the semiconductor substrate 30, a well layer 15 of the second conductivity type which is deeper than the active trenches 10 and the dummy trenches 13, and resurf layers 16 of the second conductivity type which are formed more outside than the well layer 15. A field oxide film 17 is formed on the first principal surface 31 of the semiconductor substrate 30 to cover the well layer 15 and the resurf layers 16. A gate line 18 is formed on the field oxide film 17 above the well layer 15.

The gate line 18 is covered with the interlayer insulating film 4 extending from the cell region, and a gate runner 19 is formed through the barrier metal 23 on the interlayer insulating film 4 covering the gate line 18. The gate runner 19 is connected to the gate line 18 through the barrier metal 23 and contact holes formed in the interlayer insulating film 4.

A first passivation film 20 made of a material other than an organic resin is formed to cover the gate runner 19 and a part of the emitter electrode 14 that is a metal electrode. Furthermore, a second passivation film 21 made of an organic resin is formed on the first passivation film 20 to cover a part of the emitter electrode 14 through the first passivation film 20. The first passivation film 20 is made of a material with which copper is less likely to diffuse. A silicon nitride (SiN) film is used as the material of the first passivation film 20 in Embodiment 1. Examples of the material of the first passivation film 20 may include a semi-insulating film containing nitrogen (N) and an oxidized film containing silicon (Si), besides the SiN film.

An Ni layer 24 made of nickel (Ni) is formed on the emitter electrode 14. The Ni layer 24 is connected to a portion of the emitter electrode 14 that is not covered with the first passivation film 20. An end of the Ni layer 24 sits on the first passivation film 20. The second passivation film 21 is separated from the Ni layer 24. Furthermore, an Au layer 25 made of gold (Au) is formed on the Ni layer 24. In Embodiment 1, a laminated structure of the emitter electrode 14, the Ni layer 24, and the Au layer 25 forms a top electrode of the semiconductor element 41. In other words, the top electrode according to Embodiment 1 includes the laminated structure obtained by laminating, in this order, the Au layer 25, the Ni layer 24, and the emitter electrode 14 that is an Al layer or an AlSi layer from its upper surface (a surface to which a conductive metal plate 22 to be described later is to be bonded).

The Ni layer 24 is approximately 2 μm to 15 μm thick (a vertical dimension on the plane of the paper in FIG. 2). The Au layer 25 is approximately 30 nm to 70 nm thick. The emitter electrode 14 is approximately 3 μm to 10 μm thick. The Ni layer 24 and the Au layer 25 are formed by, for example, chemical vapor deposition (CVD), physical vapor deposition (PVD) such as sputtering, or plating.

Although FIG. 2 illustrates an example of the first passivation film 20 and the second passivation film 21 at the boundary between the cell region and the terminal region of the semiconductor element 41, the first passivation film 20 and the second passivation film 21 may be formed, for example, between a plurality of IGBT cells in the cell region.

The conductive metal plate 22 is solid-phase diffusion bonded to the Au layer 25 as the top layer of the top electrode. The conductive metal plate 22 is plate-shaped, and contains Cu or a conductive metal containing Cu as a main component, such as a copper slab, a copper alloy, or a copper composite (with a copper/invar/copper (CIC) structure). The conductive metal plate 22 is approximately 0.01 mm to 1.0 mm thick. The surface (sheath) of the conductive metal plate 22 is not plated but is made of copper or a copper alloy. Thus, the surface of the conductive metal plate 22 does not contain a metal, except copper or a copper alloy. The surface of the conductive metal plate 22 may be covered with an anti-corrosive material through an anti-corrosive process.

The metal wire 47b is wire bonded to the upper surface of the conductive metal plate 22. The metal wire 47b preferably contains a material identical to that of the conductive metal plate 22 in view of higher reliability and longer life.

The conductive metal plate 22 is smaller in plane size (area) than the top electrode. Here, the conductive metal plate 22 is smaller in plane size than the Au layer 25 as the top layer of the top electrode (a layer to which the conductive metal plate 22 is bonded). In other words, the conductive metal plate 22 is positioned without extending beyond the top electrode. This facilitates the positioning of the conductive metal plate 22 with respect to the Au layer 25 when the conductive metal plate 22 is solid-phase diffusion bonded to the Au layer 25, and prevents a contact (conduction) of the conductive metal plate 22 with the other electrodes on the semiconductor element 41.

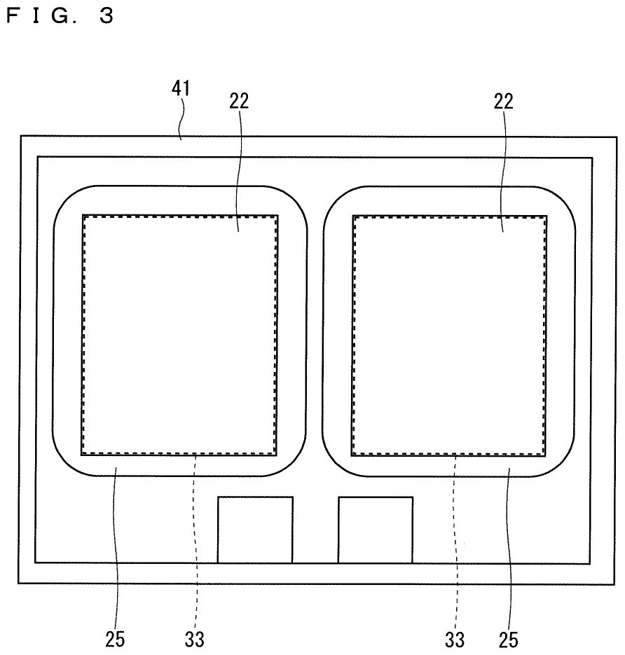

FIG. 3 illustrates an example top surface structure of the semiconductor element 41. The semiconductor element 41 in FIG. 3 includes two of the Au layers 25 as top electrodes, and two of the conductive metal plates 22 connected to the respective Au layers 25 in an overlapping manner. The conductive metal plates 22 are solid-phase diffusion bonded to the Au layers 25 by bringing an ultrasonic tool (not illustrated) in contact with upper surfaces of the conductive metal plates 22 disposed on the Au layers 25, and applying ultrasonic vibrations while applying loads on the conductive metal plates 22 to create frictions between the conductive metal plates 22 and the Au layers 25. FIG. 3 illustrates an example of forming bonded portions 33 each as an entire contact surface of the conductive metal plate 22 and the Au layer 25, using an ultrasonic tool larger in size (area) than the conductive metal plate 22.

Upon receipt of the loads and the ultrasonic vibrations from the ultrasonic tool, the upper surfaces of the conductive metal plates 22 receive ultrasonic energy to the extent that traces of the ultrasonic tool remain. Thus, atoms of the conductive metal plates 22 and the Au layers 25 diffuse to give the bonded portions 33 between the conductive metal plates 22 and the Au layers 25 sufficient bonding strength. This produces the bonded portions 33 with higher reliability. The metal wires 47 may be bonded in the same method.

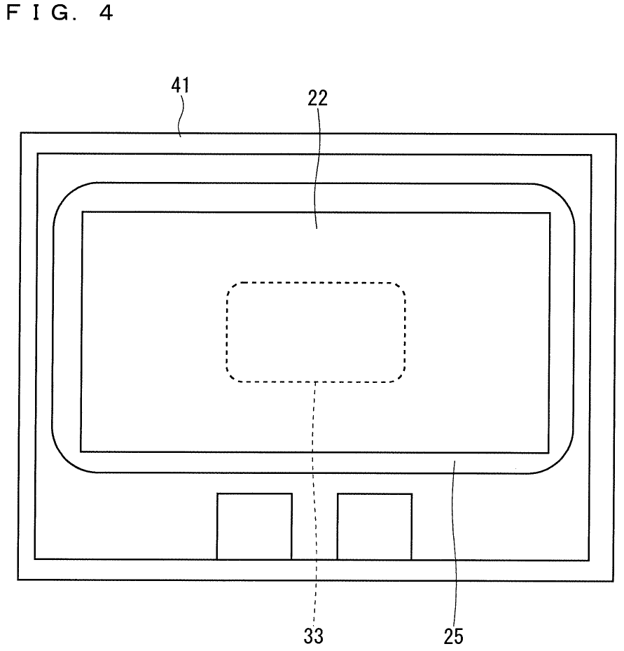

The size of each of the bonded portions 33 between the conductive metal plates 22 and the Au layers 25 varies, depending on the size of the ultrasonic tool. FIG. 4 illustrates an example where the semiconductor element 41 includes the single Au layer 25 as a top electrode and the conductive metal plate 22 is bonded to the Au layer 25. In FIG. 4, the bonded portion 33 between the conductive metal plate 22 and the Au layer 25 is smaller in size than the conductive metal plate 22, and is located at the center of the conductive metal plate 22. This bonded portion 33 is formed by solid-phase diffusion bonding the conductive metal plate 22 to the Au layer 25, by bringing an ultrasonic tool smaller in size than the conductive metal plate 22 in contact with the center of the conductive metal plate 22.

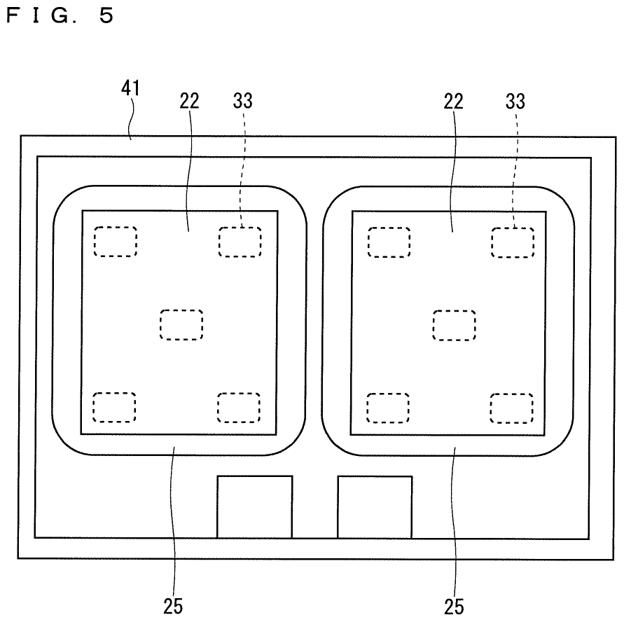

FIG. 5 illustrates an example where the semiconductor element 41 includes two of the Au layers 25 as top electrodes and the conductive metal plates 22 are bonded to the respective Au layer 25. In FIG. 5, the semiconductor element 41 includes five bonded portions 33 between each of the conductive metal plate 22 and a corresponding one of the Au layer 25, at the center and four corners of the conductive metal plate 22. These bonded portion 33 are formed by solid-phase diffusion bonding the conductive metal plates 22 to the Au layers 25 at the center and the four corners of each of the conductive metal plates 22, using an ultrasonic tool smaller in size than the conductive metal plates 22.

The vibration direction of the ultrasonic vibrations of the ultrasonic tool is a horizontal direction with respect to the contact surface between the conductive metal plate 22 and the Au layer 25. The ultrasonic tool can apply the ultrasonic vibrations in the horizontal direction (X direction) or the vertical direction (Y direction) on the plane of the paper in each of FIGS. 3 to 5. Since the ultrasonic tool can apply the ultrasonic vibrations in one direction or two directions, combining the ultrasonic vibrations in the X direction and the Y direction can produce rectangular or circular ultrasonic energy as a trajectory of laser bonding irradiation. Alternatively, the ultrasonic tool may apply ultrasonic energy in one direction or two directions while rotating the semiconductor element 41 or a stage that holds the insulating substrate 43 to which the semiconductor element 41 has been bonded. As such, combining ultrasonic vibrations in various vibration directions can reduce damages to the semiconductor element 41 which are caused by the ultrasonic vibrations, facilitate diffusion of the atoms of the conductive metal plate 22 and the Au layer 25 that is an electrode on the semiconductor element 41, and produce higher bonding strength at the bonded portion 33 between the conductive metal plate 22 and the Au layer 25.

In the semiconductor device 100 according to Embodiment 1, the top electrode of the semiconductor element 41 is not Cu plated, but the conductive metal plate 22 is solid-phase diffusion bonded to the top electrode. This can suppress an increase in the production costs. The metal wires 47 are bonded to the conductive metal plate 22. This causes fewer breaks from lift-off (peels) of wires than those in directly bonding a metal wire to a top electrode, and can contribute to higher reliability and longer life of semiconductor devices. Furthermore, the conductive metal plate 22 is a plate component whose thickness can be easily managed. Thus, the conductive metal plate 22 never suffers from non-uniform thicknesses or variations in appearance as seen in Cu plating.

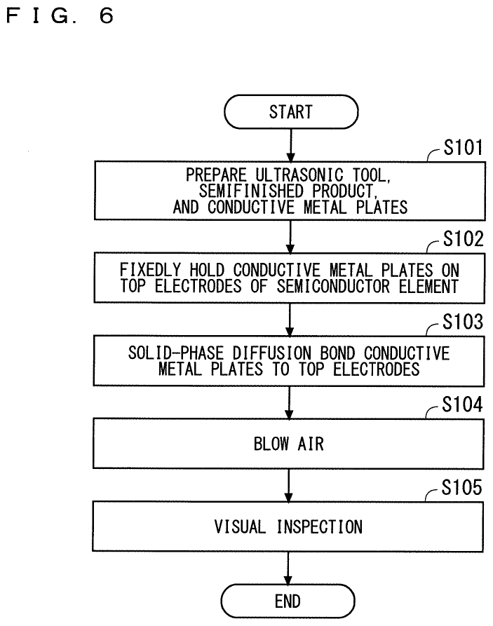

Next, a method of manufacturing the semiconductor device 100 according to Embodiment 1, particularly, a step for solid-phase diffusion bonding the conductive metal plates 22 to the semiconductor element 41 will be described with reference to the flowchart in FIG. 6.

First, an ultrasonic tool is attached to an ultrasonic bonding apparatus. Then, a semifinished product obtained by bonding the semiconductor element 41 to the insulating substrate 43, and the conductive metal plates 22 are prepared (Step S101). Here, the conductive metal plates 22 corresponding to the number of the top electrodes of the semiconductor element 41 are prepared.

The insulating substrate 43 on which the semiconductor element 41 is mounted is secured to a stage of the ultrasonic bonding apparatus by adsorption or using a pressure jig, so that the conductive metal plates 22 are mounted on the top electrodes of the semiconductor element 41. Then, the ultrasonic tool is moved downward in a direction vertical to the conductive metal plates 22 (Z direction) to press the ultrasonic tool to the conductive metal plates 22 and apply loads on the conductive metal plates 22. Thereby, the conductive metal plates 22 are fixedly held on the top electrodes of the semiconductor element 41 (Step S102). If the ultrasonic bonding apparatus includes a camera and an image recognition function and can monitor and automatically control the ultrasonic tool or operations on the stage using the camera and the image recognition function, Step S102 can be automatically performed.

Then, with application of ultrasonic vibrations and loads on the conductive metal plates 22 using the ultrasonic tool, the conductive metal plates 22 are solid-phase diffusion bonded to the top electrodes of the semiconductor element 41 (Step S103). Step S103 may be performed while the conductive metal plates 22 are heated. This increases the bonding energy given to the conductive metal plates 22 to produce the tighter bonded portions 33. However, heating is a main factor of enhancing the oxidation. Thus, when Step S103 is performed with the conductive metal plates 22 being heated, it is preferred to perform Step S103 with an inert gas such as nitrogen being injected or to perform Step S103 in an inert gas atmosphere.

As illustrated in FIG. 3 or 5, when there are a plurality of portions subjected to the solid-phase diffusion bonding, Step S103 is repeated a plurality of times.

After the solid-phase diffusion bonding is completed, the ultrasonic tool is moved upward and separated from the conductive metal plates 22. Then, air is blown to remove metal cuttings scattered on the insulating substrate 43, the semiconductor element 41, and the conductive metal plates 22 (Step S104). The metal cuttings are minute ones produced by application of the ultrasonic vibrations and the loads on the conductive metal plates 22 using the ultrasonic tool. For example, when the conductive metal plates 22 are made of Cu, minute Cu cuttings are produced.

The loads and the ultrasonic vibrations may be applied to the conductive metal plates 22 in two steps as stepped waveforms. For example, the ultrasonic vibrations may be applied with a smaller load in the first half of the solid-phase diffusion bonding step, and the ultrasonic vibrations may be applied with a larger load in the latter half.

After completion of blowing air, a visual inspection is conducted to confirm the presence of a split in the semiconductor element 41 and the presence of remaining metal cuttings (Step S105). If the ultrasonic bonding apparatus includes a camera and an image recognition function and can conduct the visual inspection using the camera and the image recognition function, Step S105 can be automatically performed. Furthermore, an automatic visual inspection apparatus separate from the ultrasonic bonding apparatus may be used.

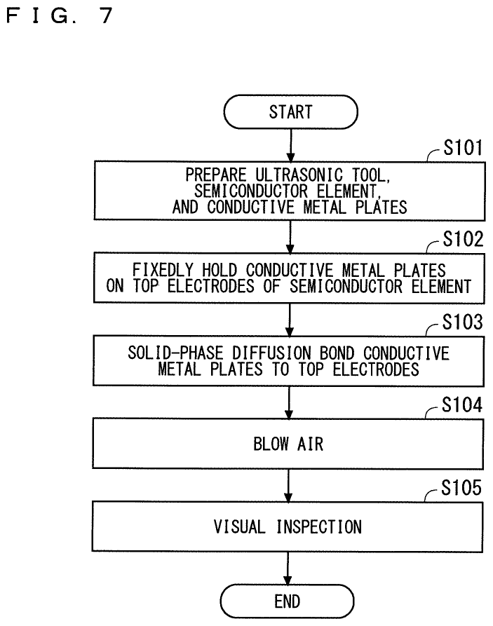

FIG. 7 illustrates a modified flowchart illustrating a step for solid-phase diffusion bonding the conductive metal plates 22 to the semiconductor element 41. Although a semifinished product of the semiconductor element 41 bonded to the insulating substrate 43 is prepared in Step S101 in the procedure of FIG. 6, the semiconductor element 41 to be bonded to the insulating substrate 43 is prepared in Step S101 in the procedure of FIG. 7. The steps of Steps S102 to S105 in the procedure of FIG. 7 are performed on the semiconductor element 41 to be bonded to the insulating substrate 43. The other details are identical to those of the procedure of FIG. 6.

If a plurality of semiconductor elements 41 are mounted on the insulating substrate 43 and any one of the semiconductor elements 41 is damaged in the solid-phase diffusion bonding step (Step S103) and becomes a defective part in the procedure of FIG. 6, all the semiconductor elements 41 on the insulating substrate 43 cannot be passed to the next step. Since the solid-phase diffusion bonding step (Step S103) is performed on each of the semiconductor elements 41 in the procedure of FIG. 7, only the semiconductor element 41 that has become a defective part should be removed. This produces an advantage of improving the manufacturing yield. This advantage is particularly effective when the semiconductor element 41 is made of expensive SiC.

After completion of the procedure of FIG. 6 or FIG. 7, the metal wire 47b is wire bonded to the conductive metal plate 22, and the casing 44 is adhesively secured onto the insulating substrate 43 with the adhesive 45. Then, the interconnection is completed with the metal wire 47a being wire bonded. Subsequently, the sealant 48 fills the space inside the casing 44 and seals the components. These steps are omitted in the flowcharts. The metal wire 47a and the metal wire 47b may be simultaneously wire bonded after the casing 44 is adhesively secured onto the insulating substrate 43.

Since no bonding material or plating is interposed between the top electrode of the semiconductor element 41 and the conductive metal plate 22 in Embodiment 1, the conductive metal plate 22 is disposed parallel to the top electrode of the semiconductor element 41. This facilitates the bonding of the metal wire 47b, and thereby produces advantages of reducing damages to the semiconductor element 41 and peels of wires.

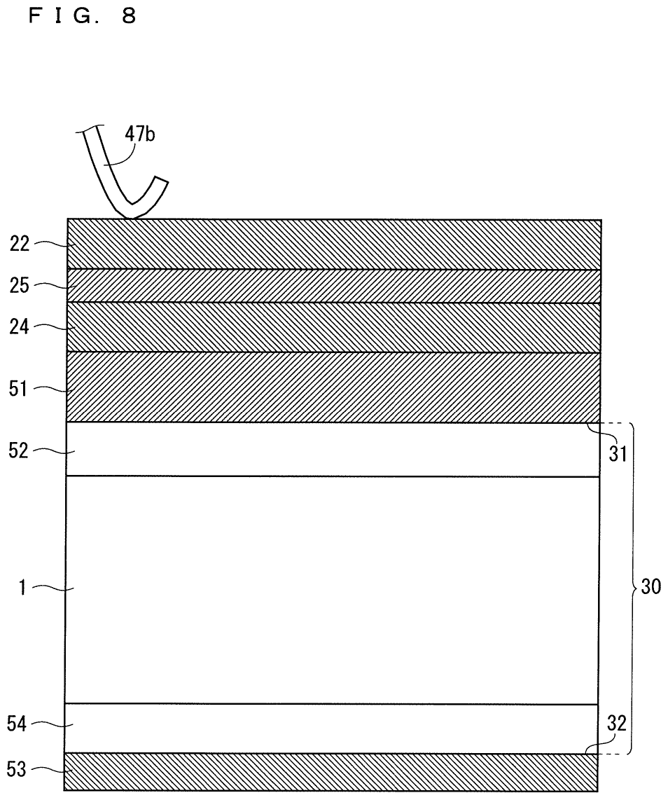

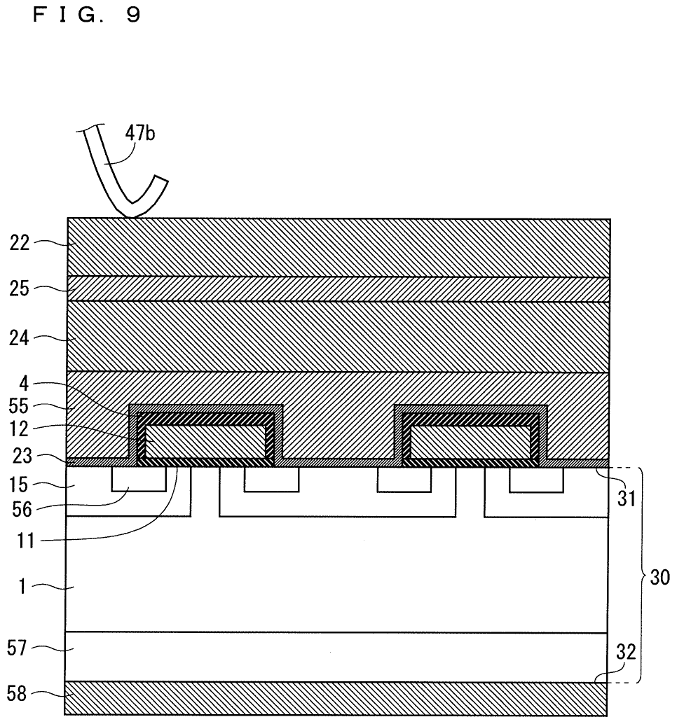

Although FIG. 2 illustrates a trench-gate IGBT as an example of the semiconductor element 41, the semiconductor element 41 is not limited to the IGBT but may be, for example, a MOSFET or a FWD. FIG. 8 illustrates an example structure of the semiconductor element 41 that is a p-n junction diode to be used as a FWD. FIG. 9 illustrates an example structure of the semiconductor element 41 that is a planar-gate MOSFET. In FIGS. 8 and 9, the constituent elements corresponding to those in FIG. 2 have the same reference numerals. Each of FIGS. 8 and 9 illustrates a cross section of the cell region.

As illustrated in FIG. 8, when the semiconductor element 41 is a p-n junction diode, an anode layer 52 of the second conductivity type is formed in a surface layer of the semiconductor substrate 30 on the first principal surface 31 side. Furthermore, an anode electrode 51 to be connected to the anode layer 52 is formed on the first principal surface 31. Furthermore, a cathode layer 54 of the first conductivity type is formed in a surface layer of the semiconductor substrate 30 on the second principal surface 32 side. Furthermore, a cathode electrode 53 to be connected to the cathode layer 54 is formed on the second principal surface 32. The Ni layer 24 and the Au layer 25 are formed on the anode electrode 51. In other words, the anode electrode 51, the Ni layer 24, and the Au layer 25 form a top electrode in the structure of FIG. 8. The conductive metal plate 22 is solid-phase diffusion bonded to the Au layer 25 as the top layer of the top electrode.

As illustrated in FIG. 9, when the semiconductor element 41 is a planar-gate MOSFET, the well layer 15 of the second conductivity type is selectively formed in a surface layer of the semiconductor substrate 30 on the first principal surface 31 side, and a source layer 56 of the first conductivity type is selectively formed in a surface layer of the well layer 15. Furthermore, the gate insulating film 11 and the gate electrode 12 are formed on the first principal surface 31 of the semiconductor substrate 30 to face the well layer 15 between the source layer 56 in the surface layer of the semiconductor substrate 30 and the drift layer 1. The gate electrode 12 is covered with the interlayer insulating film 4, and the barrier metal 23 and a source electrode 55 are formed on the interlayer insulating film 4. The source electrode 55 is connected to the source layer 56 and the well layer 15 through the barrier metal 23 and contact holes formed in the interlayer insulating film 4. Furthermore, a drain layer 57 of the first conductivity type is formed in a surface layer of the semiconductor substrate 30 on the second principal surface 32 side. Furthermore, a drain electrode 58 to be connected to the drain layer 57 is formed on the second principal surface 32. The Ni layer 24 and the Au layer 25 are formed on the source electrode 55. In other words, the source electrode 55, the Ni layer 24, and the Au layer 25 form a top electrode in the structure of FIG. 9. The conductive metal plate 22 is solid-phase diffusion bonded to the Au layer 25 as the top layer of the top electrode.

The structures in FIGS. 2, 8, and 9 are mere example structures of the semiconductor element 41. The structure of the semiconductor element 41 is not limited to these. For example, the semiconductor element 41 may be a reverse conducting IGBT (RC-IGBT) obtained by integrating an IGBT and a FWD on one semiconductor chip. Since the RC-IGBT can reduce a footprint of the semiconductor element 41, the RC-IGBT can contribute to downsizing the semiconductor device 100. The RC-IGBT has also advantages of significantly improving the productivity and the production cycle, because the RC-IGBT can reduce the number of manufacturing processes (e.g., steps for solid-phase diffusion bonding the conductive metal plates 22 to the top electrodes of the semiconductor element 41).

Although FIG. 1 illustrates a packaging structure of the semiconductor device 100 in which the semiconductor element 41 is housed in the casing 44, for example, a packaging structure in which the semiconductor element 41 is molded by a thermosetting sealant (what is called a transfer molded package) may be accepted as the packaging structure of the semiconductor device 100.

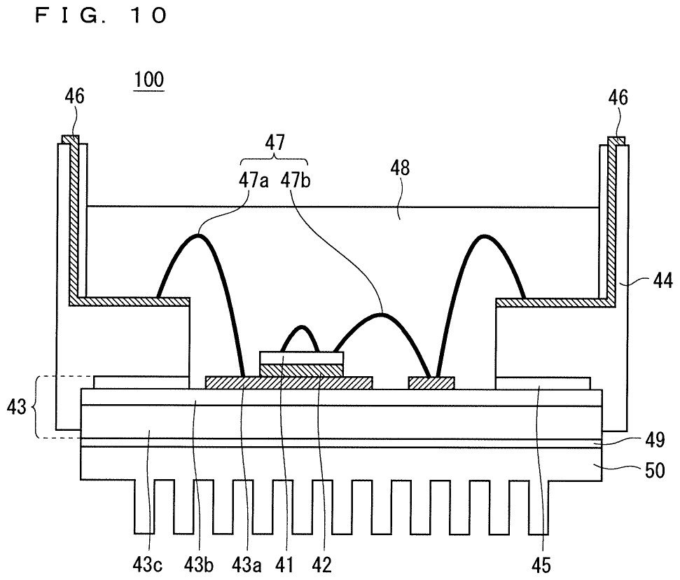

Depending on use conditions of the semiconductor device 100, it is probable that an operating temperature of the semiconductor element 41 exceeds a rated value, the switching performance of the semiconductor element 41 decreases, and the semiconductor element 41 thermally runs away and is destroyed at worst. The insulating substrate 43 having a higher thermal conductivity is preferably used for preventing the operating temperature of the semiconductor element 41 from exceeding the rated value. As illustrated in FIG. 10, a cooler 50 with a plurality of fins may be attached to a lower surface of the insulating substrate 43 (i.e., a lower surface of the base plate 43c) through a heat radiation material 49. Examples of the heat radiation material 49 include a bonding material, thermal grease, and a thermal interface material (TIM). The cooler 50 is made of a metal having a higher thermal conductivity and containing aluminum (Al) or copper (Cu). The cooler 50 may be air-cooled or water-cooled.

The insulating substrate 43 and the cooler 50 may be integrated. The integration can omit the heat radiation material 49, and reduce the thermal resistance between the insulating substrate 43 and the cooler 50. This further improves the cooling performance of the semiconductor element 41.

### Embodiment 2

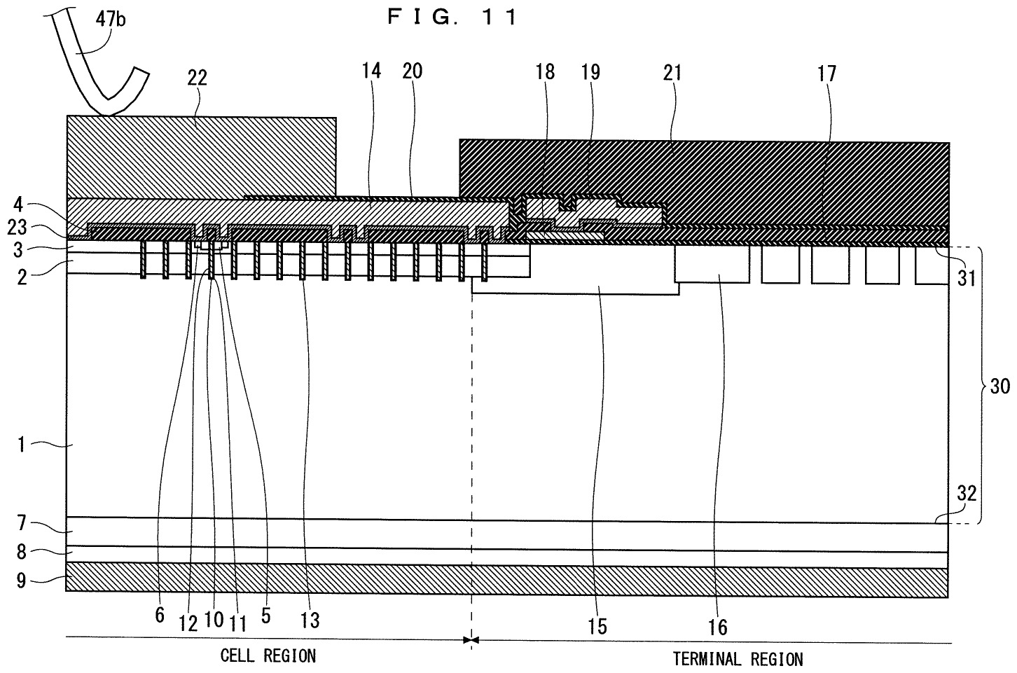

FIG. 11 illustrates a cross-sectional view of the semiconductor element 41 mounted on the semiconductor device 100 according to Embodiment 2. In FIG. 11, the constituent elements corresponding to those in FIG. 2 have the same reference numerals. Thus, the description of these is omitted, and the differences with FIG. 2 will be mainly described.

The structure in FIG. 11 is obtained by omitting the Ni layer 24 and the Au layer 25 from the structure in FIG. 2. In FIG. 11, the emitter electrode 14 is a top electrode of the semiconductor element 41, and the conductive metal plate 22 is solid-phase diffusion bonded to the emitter electrode 14.

When the conductive metal plate 22 is solid-phase diffusion bonded to the emitter electrode 14 in the structure in FIG. 11, the emitter electrode 14 is preferably thicker for preventing damages to the semiconductor element 41, for example, approximately several hundreds of nm thick. Conversely, the structure in FIG. 11 is applicable when the energy for solid-phase diffusion bonding the conductive metal plate 22 to the emitter electrode 14 can be reduced to the extent that no damage is given to the semiconductor element 41.

Embodiment 2 can reduce the number of manufacturing processes, the number of materials, and the manufacturing cost of the semiconductor device 100 by omitting the Ni layer 24 and the Au layer 25.

The whole structure and the manufacturing method of the semiconductor device 100 according to Embodiment 2 may be basically identical to those according to Embodiment 1.

### Embodiment 3

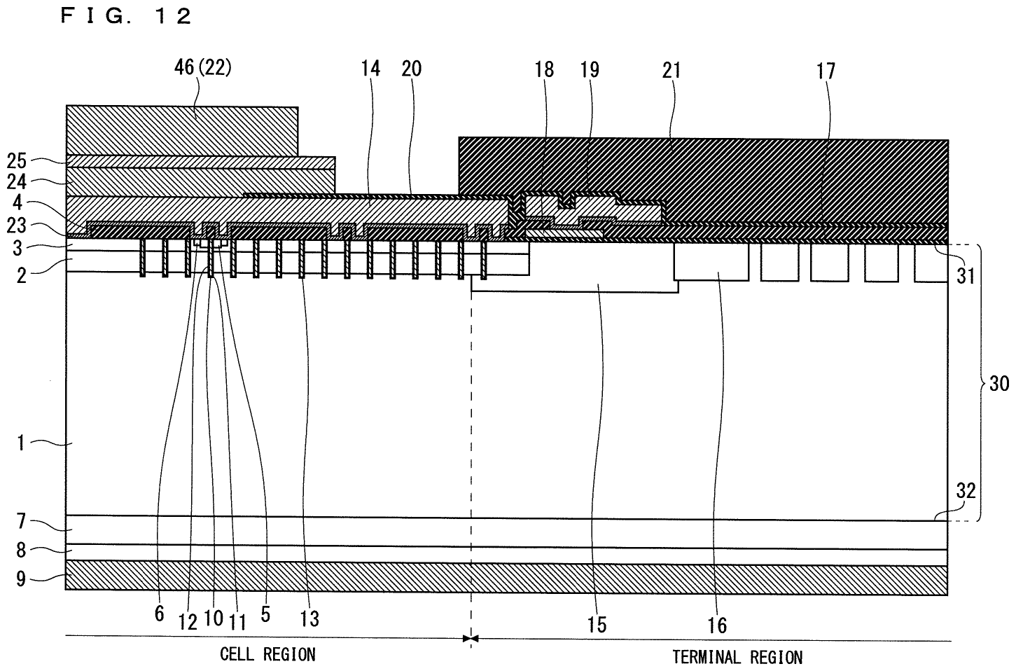

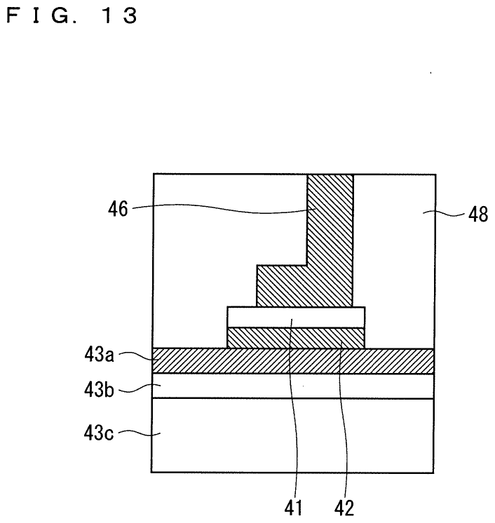

FIG. 12 illustrates a cross-sectional view of the semiconductor element 41 mounted on the semiconductor device 100 according to Embodiment 3. FIG. 13 is an enlarged cross-sectional view of the vicinity of the semiconductor element 41 in the semiconductor device 100 according to Embodiment 3. In FIGS. 12 and 13, the constituent elements corresponding to those in FIG. 1 or 2 have the same reference numerals. Thus, the description of these is omitted, and the differences with FIGS. 1 and 2 will be mainly described.

In Embodiment 3, the metal wire 47b for connecting the top electrode of the semiconductor element 41 and the electrode terminals 46 shown in FIG. 1 is omitted. Embodiment 3 differs from Embodiment 1 in that the electrode terminal 46 is directly bonded to the top electrode of the semiconductor element 41 as illustrated in FIG. 13. As illustrated in FIG. 12, the electrode terminal 46 also functions as the conductive metal plate 22, and is solid-phase diffusion bonded to the Au layer 25 as the top layer of the top electrode of the semiconductor element 41. Thus, the electrode terminal 46 is made of Cu or a conductive metal containing Cu as a main component, such as a copper slab, a copper alloy, or a copper composite (with the CIC structure), similarly to the conductive metal plate 22 according to Embodiment 1. Although one of the ends of each of the electrode terminals 46 illustrated in FIG. 1 protrudes from the casing 44, the electrode terminal 46 in FIGS. 12 and 13 may be a part of the interconnection without protruding from the casing 44, or may be independent from the casing 44 (not inserted into the casing 44).

As illustrated in FIG. 13, the electrode terminal 46 is bent to form a bonding surface with the semiconductor element 41. In the example of FIG. 13, the electrode terminal 46 is L-shaped, and the L-shaped lower surface of the electrode terminal 46 is solid-phase diffusion bonded to the Au layer 25 as the top layer of the top electrode of the semiconductor element 41. Furthermore, the electrode terminal 46 may be bent-shaped, which can reduce stresses produced under a use environment of the semiconductor device 100. The thickness of the electrode terminal 46 is set according to the specification of the semiconductor device 100 or a passing current, for example, approximately ranges from 0.4 mm to 1.5 mm.

The whole structure and the manufacturing method of the semiconductor device 100 according to Embodiment 3 may be basically identical to those according to Embodiment 1.

### Embodiment 4

Embodiment 4 will describe a power conversion device to which the semiconductor devices according to Embodiments 1 to 3 are applied. Although the power conversion device according to Embodiment 4 is not limited to a specific power conversion device, Embodiment 4 will describe application of the semiconductor devices according to Embodiments 1 to 3 to a three-phase inverter.

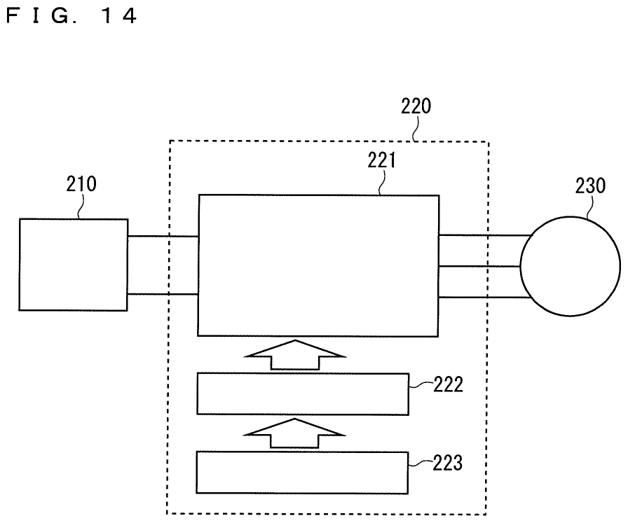

FIG. 14 is a block diagram illustrating a configuration of a power conversion system to which the power conversion device according to Embodiment 4 has been applied. The power conversion system illustrated in FIG. 14 includes a power supply 210, a power conversion device 220, and a load 230. The power supply 210, which is a DC power supply, supplies a DC power to the power conversion device 220. The power supply 210 may include various components such as a DC system, a solar battery, or a rechargeable battery, and a rectifying circuit connected to an AC system or an AC/DC converter. The power supply 210 may include a DC/DC converter which converts the DC power output from the DC system into a predetermined power.

The power conversion device 220, which is a three-phase inverter connected between the power supply 210 and the load 230, converts the DC power supplied from the power supply 210 into the AC power to supply the AC power to the load 230. As illustrated in FIG. 14, the power conversion device 220 includes a main conversion circuit 221 that converts the DC power into the AC power, a drive circuit 222 that outputs a driving signal for driving each switching element in the main conversion circuit 221, and a control circuit 223 that outputs, to the drive circuit 222, a control signal for controlling the drive circuit 222.

The load 230 is a three-phase electrical motor driven by the AC power supplied from the power conversion device 220. The load 230 is not limited to specific use but is an electrical motor mounted on various types of electrical devices. Thus, the load 230 is used as an electrical motor for, for example, a hybrid car, an electrical car, a rail vehicle, an elevator, or air-conditioning equipment.

The power conversion device 220 will be described in detail hereinafter. The main conversion circuit 221 includes switching elements and free-wheeling diodes (not illustrated). Switching of the switching element causes the DC power supplied from the power supply 210 to be converted into the AC power. The main conversion circuit 221 then supplies the AC power to the load 230. The specific circuit configuration of the main conversion circuit 221 is of various types. The main conversion circuit 221 according to Embodiment 4 is a three-phase full-bridge circuit having two levels, and includes six switching elements and six free-wheeling diodes anti-parallel connected to the respective switching elements. The semiconductor device 100 according to any one of Embodiments 1 to 3 is applied to each of the switching elements of the main conversion circuit 221. Embodiment 4 will describe the switching elements of the main conversion circuit 221 to each of which the semiconductor device 100 according to Embodiment 1 has been applied. The six switching elements form three pairs of upper and lower arms in each pair of which the two switching elements are serially connected to each other. The three pairs of upper and lower arms form the respective phases (U-phase, V-phase, and W-phase) of the full-bridge circuit. Output terminals of the respective pairs of upper and lower arms, i.e., three output terminals of the main conversion circuit 221 are connected to the load 230.

The drive circuit 222 generates drive signals for driving the switching elements of the main conversion circuit 221, and supplies the drive signals to control electrodes of the switching elements of the main conversion circuit 221. Specifically, the drive circuit 222 outputs the drive signal for switching each of the switching elements to an ON state and the drive signal for switching the switching element to an OFF state, to the control electrode of the switching element in accordance with the control signal from the control circuit 223 to be described later. When the switching element is kept in the ON state, the drive signal is a voltage signal (ON signal) higher than or equal to a threshold voltage of the switching element. When the switching element is kept in the OFF state, the drive signal is a voltage signal (OFF signal) lower than or equal to the threshold voltage of the switching element.

The control circuit 223 controls the switching elements of the main conversion circuit 221 to supply a desired power to the load 230. Specifically, the control circuit 223 calculates a time (ON time) when each of the switching elements of the main conversion circuit 221 needs to enter the ON state, based on the power which needs to be supplied to the load 230. For example, the control circuit 223 can control the main conversion circuit 221 by performing PWN control for modulating the ON time of the switching elements in accordance with the voltage which needs to be output. Then, the control circuit 223 outputs a control instruction (control signal) to the drive circuit 222 so that the drive circuit 222 outputs the ON signal to the switching element which needs to enter the ON state and outputs the OFF signal to the switching element which needs to enter the OFF state at each time. The drive circuit 222 outputs the ON signal or the OFF signal as the drive signal to the control electrode of each of the switching elements in accordance with this control signal.

Since the power semiconductor devices according to Embodiments 1 to 3 are applied as the switching elements of the main conversion circuit 221 in the power conversion device 220 according to Embodiment 4, the reliability can be enhanced.

Although Embodiment 4 describes the power conversion device 220 having the two levels, Embodiment 4 is not limited to this but can be applied to various power conversion devices 220. Although Embodiment 4 describes the power conversion device 220 having the two levels, the power conversion device 220 may have three or multiple levels. Embodiments 1 to 3 may be applied to a single-phase inverter when the power is supplied to the single-phase load 230. Embodiments 1 to 3 are also applicable to a DC/DC converter or an AC/DC converter when the power is supplied to, for example, the DC load 230.

The load 230 for the power conversion device 220 to which the semiconductor devices 100 according to Embodiments 1 to 3 are applied is not limited to an electrical motor. The power conversion device 220 is also applicable as a power-supply device of an electrical discharge machine, a laser beam machine, an induction heat cooking device, or a non-contact power feeding system, and is further applicable as a power conditioner of, for example, a solar power system or an electricity storage system.

Embodiments can be freely combined, and appropriately modified or omitted.

### APPENDIXES

The following will describe a summary of various aspects of the present disclosure as appendixes.

### Appendix 1

A semiconductor device, comprising:
a semiconductor element;
a top electrode on an upper surface of the semiconductor element; and
a conductive metal plate containing copper as a main component and solid-phase diffusion bonded to the top electrode of the semiconductor element.

### Appendix 2

The semiconductor device according to appendix 1,
wherein the top electrode includes a laminated structure obtained by laminating, in this order, an Au layer, an Ni layer, and an Al layer or an AlSi layer from a surface to which the conductive metal plate is solid-phase diffusion bonded.

### Appendix 3

The semiconductor device according to appendix 2,
wherein the top electrode is formed on an interlayer insulating film, and
the semiconductor device comprises a barrier metal between the interlayer insulating film and the Al layer or the AlSi layer in the top electrode, the barrier metal containing Ti or W.

### Appendix 4

The semiconductor device according to appendix 3,
wherein the Au layer is 30 nm to 70 nm thick, the Ni layer is 2 μm to 15 μm thick, the Al layer or the AlSi layer is 3 μm to 10 μm thick, and the barrier metal is 10 nm to 300 nm thick.

### Appendix 5

The semiconductor device according to appendix 1,
wherein the top electrode includes an Al layer or an AlSi layer on a surface to which the conductive metal plate is solid-phase diffusion bonded.

### Appendix 6

The semiconductor device according to appendix 5,
wherein the top electrode is formed on an interlayer insulating film, and
the semiconductor device comprises a barrier metal between the interlayer insulating film and the Al layer or the AlSi layer in the top electrode, the barrier metal containing Ti or W.

### Appendix 7

The semiconductor device according to one of appendixes 1 to 6,
wherein the conductive metal plate is smaller in plane size than the top electrode, the conductive metal plate being positioned without extending beyond the top electrode.

### Appendix 8

The semiconductor device according to one of appendixes 1 to 7,
wherein the conductive metal plate is 0.01 mm to 1.0 mm thick.

### Appendix 9

The semiconductor device according to one of appendixes 1 to 8, comprising
a plurality of top electrodes on the upper surface of the semiconductor element, and a plurality of conductive metal plates on the respective top electrodes, the plurality of top electrodes including the top electrode, the plurality of conductive metal plates including the conductive metal plate.

### Appendix 10

The semiconductor device according to one of appendixes 1 to 9,
wherein the conductive metal plate is solid-phase diffusion bonded to the top electrode of the semiconductor element at a plurality of portions.

### Appendix 11

The semiconductor device according to one of appendixes 1 to 10, comprising
a metal wire solid-phase diffusion bonded to the conductive metal plate, the metal wire containing a material identical to a material of the conductive metal plate.

### Appendix 12

The semiconductor device according to one of appendixes 1 to 10,
wherein the conductive metal plate is an electrode terminal including an L-shaped end whose lower surface is solid-phase diffusion bonded to the top electrode.

### Appendix 13

The semiconductor device according to one of appendixes 1 to 12,
wherein the semiconductor element is a reverse-conducting insulated gate bipolar transistor.

### Appendix 14

The semiconductor device according to one of appendixes 1 to 13,
wherein the semiconductor element contains a wide-bandgap semiconductor.

### Appendix 15

A power conversion device, comprising:
a main conversion circuit including the semiconductor device according to one of appendixes 1 to 14, the main conversion circuit converting an input power to output a resulting power;
a drive circuit outputting, to the semiconductor device, a driving signal for driving the semiconductor device; and
a control circuit outputting, to the drive circuit, a control signal for controlling the drive circuit.

### Appendix 16

A method of manufacturing a semiconductor device, the method comprising:
preparing an ultrasonic tool, a semiconductor element, and a conductive metal plate;
placing the semiconductor element on a stage, placing the conductive metal plate on a top electrode of the semiconductor element, and fixedly holding the conductive metal plate on the top electrode using the ultrasonic tool;
applying a load and ultrasonic vibrations from the ultrasonic tool on the conductive metal plate to solid-phase diffusion bond the conductive metal plate to the top electrode;
blowing air on the semiconductor element to which the conductive metal plate has been solid-phase diffusion bonded; and
conducting a visual inspection on the semiconductor element on which the air has been blown.

### Appendix 17

The method according to appendix 16,
wherein the preparing includes preparing the semiconductor element bonded to an insulating substrate.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor element;
a top electrode on an upper surface of the semiconductor element; and
a conductive metal plate containing copper as a main component and solid-phase diffusion bonded to the top electrode of the semiconductor element.

2. The semiconductor device according to claim 1,
wherein the top electrode includes a laminated structure obtained by laminating, in this order, an Au layer, an Ni layer, and an Al layer or an AlSi layer from a surface to which the conductive metal plate is solid-phase diffusion bonded.

3. The semiconductor device according to claim 2,
wherein the top electrode is formed on an interlayer insulating film, and
the semiconductor device comprises a barrier metal between the interlayer insulating film and the Al layer or the AlSi layer in the top electrode, the barrier metal containing Ti or W.

4. The semiconductor device according to claim 3,
wherein the Au layer is 30 nm to 70 nm thick, the Ni layer is 2 μm to 15 μm thick, the Al layer or the AlSi layer is 3 μm to 10 μm thick, and the barrier metal is 10 nm to 300 nm thick.

5. The semiconductor device according to claim 1,
wherein the top electrode includes an Al layer or an AlSi layer on a surface to which the conductive metal plate is solid-phase diffusion bonded.

6. The semiconductor device according to claim 5,
wherein the top electrode is formed on an interlayer insulating film, and
the semiconductor device comprises a barrier metal between the interlayer insulating film and the Al layer or the AlSi layer in the top electrode, the barrier metal containing Ti or W.

7. The semiconductor device according to claim 1,
wherein the conductive metal plate is smaller in plane size than the top electrode, the conductive metal plate being positioned without extending beyond the top electrode.

8. The semiconductor device according to claim 1,
wherein the conductive metal plate is 0.01 mm to 1.0 mm thick.

9. The semiconductor device according to claim 1, comprising
a plurality of top electrodes on the upper surface of the semiconductor element, and a plurality of conductive metal plates on the respective top electrodes, the plurality of top electrodes including the top electrode, the plurality of conductive metal plates including the conductive metal plate.

10. The semiconductor device according to claim 1,
wherein the conductive metal plate is solid-phase diffusion bonded to the top electrode of the semiconductor element at a plurality of portions.

11. The semiconductor device according to claim 1, comprising
a metal wire solid-phase diffusion bonded to the conductive metal plate, the metal wire containing a material identical to a material of the conductive metal plate.

12. The semiconductor device according to claim 1,
wherein the conductive metal plate is an electrode terminal including an L-shaped end whose lower surface is solid-phase diffusion bonded to the top electrode.

13. The semiconductor device according to claim 1,
wherein the semiconductor element is a reverse-conducting insulated gate bipolar transistor.

14. The semiconductor device according to claim 1,
wherein the semiconductor element contains a wide-bandgap semiconductor.

15. A power conversion device, comprising:
a main conversion circuit including the semiconductor device according to claim 1, the main conversion circuit converting an input power to output a resulting power;
a drive circuit outputting, to the semiconductor device, a driving signal for driving the semiconductor device; and
a control circuit outputting, to the drive circuit, a control signal for controlling the drive circuit.

16. A method of manufacturing a semiconductor device, the method comprising:
preparing an ultrasonic tool, a semiconductor element, and a conductive metal plate;
placing the semiconductor element on a stage, placing the conductive metal plate on a top electrode of the semiconductor element, and fixedly holding the conductive metal plate on the top electrode using the ultrasonic tool;
applying a load and ultrasonic vibrations from the ultrasonic tool on the conductive metal plate to solid-phase diffusion bond the conductive metal plate to the top electrode;
blowing air on the semiconductor element to which the conductive metal plate has been solid-phase diffusion bonded; and
conducting a visual inspection on the semiconductor element on which the air has been blown.

17. The method according to claim 16,
wherein the preparing includes preparing the semiconductor element bonded to an insulating substrate.
